(19) United States
(12) Patent Application Publication
(10) Pub. No.: US 2018/0292865 A1
(43) Pub. Date: Oct. 11, 2018

(54) MOBILE TERMINALS HAVING HOME BUTTON AND DISPLAY PANELS THEREOF

(71) Applicant: Wuhan China Star Optoelectronics Technology Co., Ltd., Wuhan, Hubei (CN)

(72) Inventors: Zuomin LIAO, Shenzhen, Guangdong (CN); Liang MA, Shenzhen, Guangdong (CN)

(73) Assignee: Wuhan China Star Optoelectronics Technology Co. Ltd., Wuhan, Hubei (CN)

(21) Appl. No.: 15/525,582

(22) PCT Filed: Apr. 13, 2017
(86) PCT No.: PCT/CN2017/080399

§ 371 Date: May 9, 2017

(30) Foreign Application Priority Data
Mar. 20, 2017 (CN) 201710165521.6

(51) Int. Cl. G06F 1/16; G06F 3/02; H05K 1/18; H05K 1/11

(52) U.S. Cl. CPC G06F 1/1684; G06F 3/0202; H05K 1/189; H05K 2201/09172; G06F 2203/04102; H05K 2201/10128; H05K 2201/09163; H05K 1/118

(57) ABSTRACT

The present disclosure relates to a mobile terminal having a Home button and a display panel thereof. The display panel includes:a display area and an external pin bonding area configured below the display area, wherein a down edge of the external pin bonding area connects to a flexible printed circuit (FPC). A slot is configured on the FPC, and the Home button is configured on a top of the slot. The slot is configured to prevent the Home button from being overlapped with at least one electrical connection area of the FPC and the external pin bonding area when the Home button is pressed, so as to avoid influence on an electrical connection of the FPC and the external pin bonding area.

### BACKGROUND OF THE INVENTION

### 1. Field of the Invention

The present disclosure relates to mobile terminals technique field,more particularly to a mobile terminal having a home button and a display panel thereof.

### 2. Discussion of the Related Art

Currently, the sales ranked first in the mobile terminal market is iPhone. The consumers have accustomed to iPhone due to its unique Home button feature. So that, mobile phones and tablets containing the Home button have been the mainstream trend. The functions of the home button include black screen wake up and fingerprint recognition. In addition, the entire panel only has one button, and it's beautiful and practical.

However, except for the Home button of the iPhone, there is no other better Home button design.

### SUMMARY

The present disclosure relates to mobile terminal having a home button and a display panel thereof.

In one aspect, the mobile terminal includes: a display panel for a Home button, including:a display area; and an external pin bonding area configured below the display area;wherein a down edge of the external pin bonding area connects to a flexible printed circuit (FPC); a slot is configured on the FPC, and the Home button is configured on a top of the slot; the slot is configured to prevent the Home button from being overlapped with at least one electrical connection area of the FPC and the external pin bonding area when the Home button is pressed, so as to avoid influence on an electrical connection of the FPC and the external pin bonding area;wherein the FPC includes a first FPC area, a second FPC area and a third FPC area connecting a bottom of the first FPC area and a bottom of the second FPC area; the first FPC area, the second FPC area, and the third FPC area cooperatively form the slot;wherein the display panel further includes an integrated circuit (IC) configured within the external pin bonding area, and the IC is in a rim of the display area.

In another aspect, the present disclosure further relates to a display panel for a Home button, including:a display area; and an external pin bonding area configured below the display area;wherein a down edge of the external pin bonding area connects to a FPC; a slot is configured on the FPC, and the Home button is configured on a top of the slot; the slot is configured to prevent the Home button from being overlapped with at least one electrical connection area of the FPC and the external pin bonding area when the Home button is pressed, so as to avoid influence on the electrical connection of the FPC and the external pin bonding area.

In another aspect,the present disclosure further relates to a mobile terminal having a home button, including:a display panel;a Home button configured within the display panel;a backlight module configured to provide backlight to the display panel;wherein the display panel includes:a display area; and an external pin bonding area configured below the display area;wherein a down edge of the external pin bonding area connects to a FPC; a slot is configured on the FPC, and the Home button is configured on a top of the slot; the slot is configured to prevent the Home button from being overlapped with at least one electrical connection area of the FPC and the external pin bonding area when the Home button is pressed, so as to avoid influence on the electrical connection of the FPC and the external pin bonding area.

In view of the above,the slot is configured within the mobile terminal having the Home button and the slot is configured on the FPC of the display panel, the electrical connecting area of the FPC and the external pin bonding area may be avoided when the Home button is pressed. As such, the influence on the electrical connection between the FPC and the external pin bonding area may be avoided.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a simplified schematic view of a display panel having a Home button in accordance with one embodiment of the present disclosure.

FIG. 2 is a side view of a mobile terminal having a Home button in accordance with one embodiment of the present disclosure.

FIG. 3 is a simplified schematic view of the mobile terminal having the Home button in accordance with one embodiment of the present disclosure.

### DETAILED DESCRIPTION OF THE EMBODIMENTS

Embodiments of the invention will now be described more fully hereinafter with reference to the accompanying drawings, in which embodiments of the invention are shown. The figure and the embodiment described according to figure are only for illustration, and the present disclosure is not limited to these embodiments.

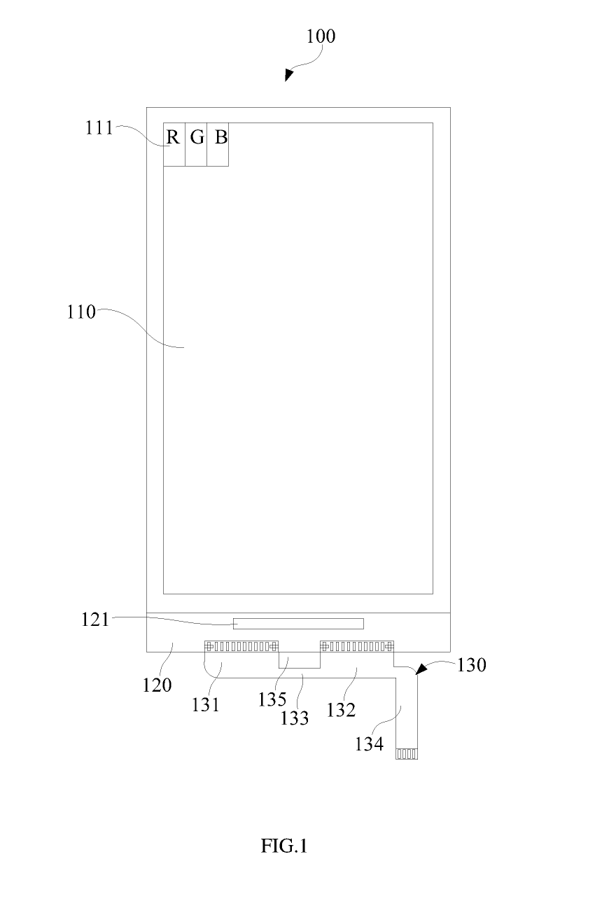

FIG. 1 is a simplified schematic view of a display panel having a Home button in accordance with one embodiment of the present disclosure.

As shown in FIG. 1, the present disclosure relates to a display panel 100 for a Home button. The display panel 100 includes a display area 110 and an external pin bonding area 120. A plurality of red, green, blue (RGB) pixel cells 111 are configured within the display area 110 in matrix. However, only one RGB pixel cell 111 is shown in FIG. 1.

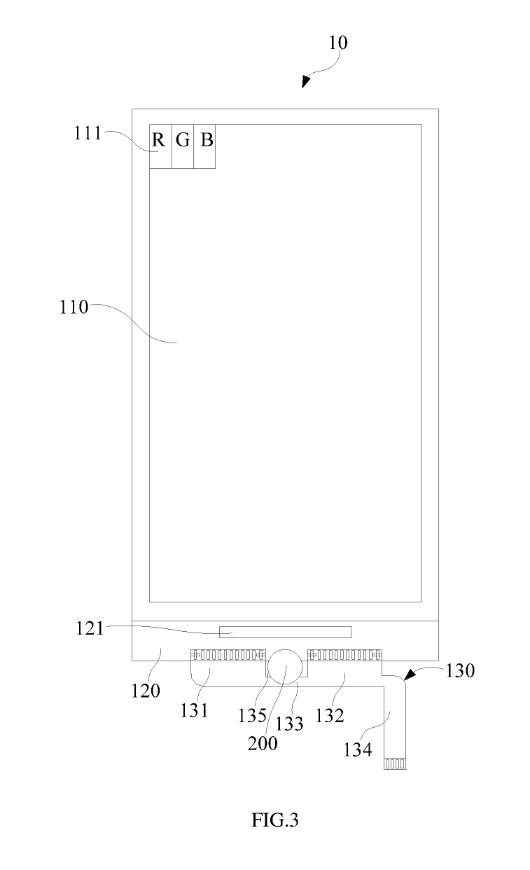

The external bonding area 120 is configured below the display area 110. A down edge of the external bonding area 120 connects to a flexible printed circuit (FPC) 130.A slot 135 is configured on the FPC 130, and the Home button 200 (as shown in FIG. 3) is configured on a top of the slot 135.The slot 135 is configured to prevent the Home button 200 from being overlapped with at least one electrical connection area 120 of the FPC 130 and the external pin bonding area 120 when the Home button 200 is pressed, so as to avoid influence on an electrical connection of the FPC 130 and the external pin bonding area 120.

Specifically, the FPC 130 includes: a first FPC area 131, a second FPC area 132 and a third FPC area 133 connecting a bottom of the first FPC area 131 and a bottom of the second FPC area 132. The first FPC area 131, the second FPC area 132, and the third FPC area 133 cooperatively form the slot 135. The first FPC area 131 and the second FPC area 132 electrically connect to the external pin bonding area 120. The first FPC area 131 includes two end corners configured on an upper end of the first FPC area 131, and two the second FPC area 132 includes two end corners configured on an upper end of the second FPC area 132. A least one alignment marks are configured on the two end corners of the first FPC area 131 and on the two end corners of the second FPC area 132, so as to ensure the first FPC area 131 and the second FPC area 132 may electrically connect to the external pin bonding area 120 precisely.

The FPC 130 further includes a fourth area 134 extending from the second FPC area 132. The fourth area 134 is configured to connect to a power supply, such as to connect a circuit board of a mobile terminal. In one example, the fourth FPC area may extend from the first FPC area 131 or the third FPC area 133, but the extending position of the fourth area is not limited in the present disclosure.

In one embodiment, when the Home button is configured on a top of the slot 135, a right side of the Home button 200 and a left side of the Home button 200 are respectively spaced apart from the first FPC area 131 and the second FPC area 132, and the Home button 200 overlaps with at least one portion of the external pin bonding area 120. In one example, as shown in FIG. 1,only an upper side of the Home button 200 overlaps with the external pin bonding area 120, i.e., a partial overlap. In another example, the upper side and a down side of the Home button 200 are configured within the external bonding area 120, i.e., a complete overlap. Therefore, the slot 135 configured on the FPC 130 may not only be configured to prevent the Home button 200 from being overlapped with at least one electrical connection area of the FPC 130 and the external pin bonding area 120 when the Home button is pressed, but may also reduce a thickness of the mobile terminal.

In one example, the display panel 100 further includes an integrated circuit (IC) 121 configured on the external pin bonding area 120,and the IC 121 is in a rim of the display area 110. The IC 121 is configured to drive the RGB pixel cells 111 to display corresponding images. However, it does not relate to the present disclosure, and may not be described here.

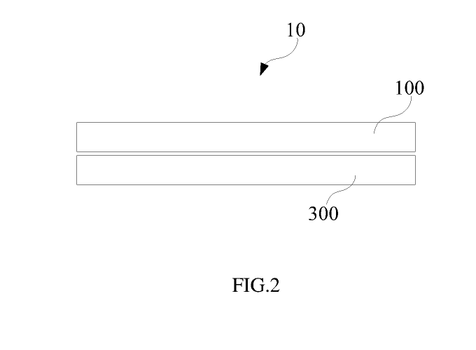

Referring to FIG. 2 and FIG. 3, FIG. 2 is a side view of the mobile terminal having the Home button in accordance with one embodiment of the present disclosure, and FIG. 3 is a simplified schematic view of the mobile terminal having the Home button in accordance with one embodiment of the present disclosure.

As shown in FIG. 2, the present disclosure further relates to a mobile terminal 10 having the home button. The mobile terminal 10includes: the display panel 100, the Home button 200 configured within the display panel, and a backlight module 300 configured to provide backlight to the display panel 100.

Wherein the display panel 100 includes:the display area 110 and the external pin bonding area 120, and the RGB pixel cells 111 are configured within the display area 110 in matrix. However, only one RGB pixel cell 111 is shown in FIG. 1.

The external bonding area 120 is configured below the display area 110. The down edge of the external bonding area 120 connects to the FPC 130.The slot 135 is configured on the FPC 130, and the Home button 200 is configured on the top of the slot 135.The slot 135 is configured to prevent the Home button 200 from being overlapped with the electrical connection area 120 of the FPC 130 and the external pin bonding area 120 when the Home button 200 is pressed, so as to avoid influence on the electrical connection of the FPC 130 and the external pin bonding area 120.

Specifically, the FPC 130 includes the first FPC area 131, the second FPC area 132 and the third FPC area 133 connecting the bottom of the first FPC area 131 and the bottom of the second FPC area 132. The first FPC area 131, the second FPC area 132, and the third FPC area 133 cooperatively form the slot 135. The first FPC area 131 and the second FPC area 132 electrically connect to the external pin bonding area 120. The first FPC area 131 includes two end corners configured on the upper end of the first FPC area 131, and two the second FPC area 132 includes two end corners configured on the upper end of the second FPC area 132. The alignment marks are configured on the two end corners of the first FPC area 131 and on the two end corners of the second FPC area 132, so as to ensure the first FPC area 131 and the second FPC area 132 may electrically connect to the external pin bonding area 120 precisely.

The FPC 130 further includes the fourth area 134 extending from the second FPC area 132. The fourth area 134 is configured to connect to the power supply, such as to connect the circuit board of the mobile terminal. In one example, the fourth FPC area may extend from the first FPC area 131 or the third FPC area 133, but the extending position of the fourth area is not limited in the present disclosure.

In one embodiment, when the Home button is configured on the top of the slot 135, the right side of the Home button 200 and the left side of the Home button 200 are respectively spaced apart from the first FPC area 131 and the second FPC area 132, and the Home button 200 overlaps with the external pin bonding area 120. In one example, as shown in FIG. 1, only the upper side of the Home button 200 overlaps with the external pin bonding area 120, i.e., the partial overlap. In another example, the upper side and the down side of the Home button 200 are configured within the external bonding area 120, i.e., the complete overlap. Therefore, the slot 135 configured on the FPC 130 may not only be configured to prevent the Home button 200 from being overlapped with the electrical connection area of the FPC 130 and the external pin bonding area 120 when the Home button is pressed, but may also reduce the thickness of the mobile terminal.

In one example, the display panel 100 further includes the IC 121 configured on the external pin bonding area 120,and the IC 121 is in the rim of the display area 110. The IC 121 is configured to drive the RGB pixel cell 111 to display corresponding images. However, it does not relate to the present disclosure, and may not be described here.

In view of the above, the present disclosure relates to the mobile terminal 10 having the Home button and the display panel 100 thereof. The slot 135 is configured on the FPC 130, such that the Home button 200 may be prevented from being overlapped with electrical connection area of the FPC 130 and the external pin bonding area 120 when the Home button 200 is pressed, so as to avoid the influence on the electrical connection of the FPC 130 and the external pin bonding area 120.

It is believed that the present disclosure is fully described by the embodiments, however, certain improvements and modifications may be made by those skilled in the art without departing from the principles of the present application, and such improvements and modifications shall be regarded as the scope of the present application.

What is claimed is:

1. A display panel for a Home button, comprising:
a display area; and
an external pin bonding area configured below the display area;
wherein a down edge of the external pin bonding area connects to a flexible printed circuit (FPC); a slot is configured on the FPC, and the Home button is configured on a top of the slot;
the slot is configured to prevent the Home button from being overlapped with at least one electrical connection area of the FPC and the external pin bonding area when the Home button is pressed, so as to avoid influence on an electrical connection of the FPC and the external pin bonding area;
wherein the FPC comprises a first FPC area, a second FPC area and a third FPC area connecting a bottom of the first FPC area and a bottom of the second FPC area; the first FPC area, the second FPC area, and the third FPC area cooperatively form the slot;
wherein the display panel further comprises an integrated circuit(IC)configured within the external pin bonding area, and the IC is in a rim of the display area.

2. The display panel for the Home button according to claim 1, wherein the FPC further comprises a fourth area extending from the second FPC area.

3. The display panel for the Home button according to claim 1, wherein a right side of the Home button and a left side of the Home button are respectively spaced apart from the first FPC area and the second FPC area;the Home button overlaps with the external pin bonding area.

4. A display panel for a Home button, comprising:
a display area; and
an external pin bonding area configured below the display area;
wherein a down edge of the external pin bonding area connects to a FPC; a slot is configured on the FPC, and the Home button is configured on a top of the slot; the slot is configured to prevent the Home button from being overlapped with at least one electrical connection area of the FPC and the external pin bonding area when the Home button is pressed, so as to avoid influence on the electrical connection of the FPC and the external pin bonding area.

5. The display panel for the Home button according to claim 4, wherein the FPC comprises a first FPC area, a second FPC area and a third FPC area connecting a bottom of the first FPC area and a bottom of the second FPC area; the first FPC area, the second FPC area, and the third FPC area cooperatively form the slot.

6. The display panel for the Home button according to claim 5, wherein the FPC further comprises a fourth area extending from the second FPC area.

7. The display panel for the Home button according to claim 5, wherein a right side of the Home button and a left side of the Home button are respectively spaced apart from the first FPC area and the second FPC area; the Home button overlaps with the external pin bonding area.

8. The display panel for the Home button according to claim 4, wherein the display panel further comprises an IC configured within the external pin bonding area, and the IC is in a rim of the display area.

9. A mobile terminal having a home button, comprising:
a display panel;
a Home button configured within the display panel;
a backlight module configured to provide backlight to the display panel;
wherein the display panel comprises:
a display area; and
an external pin bonding area configured below the display area;
wherein a down edge of the external pin bonding area connects to a FPC; a slot is configured on the FPC, and the Home button is configured on a top of the slot; the slot is configured to prevent the Home button from being overlapped with at least one electrical connection area of the FPC and the external pin bonding area when the Home button is pressed, so as to avoid influence on the electrical connection of the FPC and the external pin bonding area.

10. The mobile terminal having the home button according to claim 9, wherein the FPC comprises a first FPC area, a second FPC area and a third FPC area connecting a bottom of the first FPC area and a bottom of the second FPC area; the display panel further comprises an IC configured within the external pin bonding area, and the IC is in a rim of the display area; the first FPC area, the second FPC area, and the third FPC area cooperative form the slot.

11. The mobile terminal having the home button according to claim 10, wherein the FPC further comprises a fourth area extending from the second FPC area.

12. The mobile terminal having the home button according to claim 10, wherein a right side of the Home button and a left side of the Home button are respectively spaced apart from the first FPC area and the second FPC area; the Home button overlaps with the external pin bonding area.

13. The mobile terminal having the home button according to claim 9, wherein the display panel further comprises an IC configured within the external pin bonding area, and the IC is in a rim of the display area.
